(19) United States
(12) Patent Application Publication
(10) Pub. No.: US 2026/0149263 A1
(43) Pub. Date: May 28, 2026

(54) SAFELY UNLOCKING DC VOLTAGE SOURCES

(71) Applicant: ZF Friedrichshafen AG, Friedrichshafen (DE)

(72) Inventors: Sebastian GOTTSCHALLER, Tiefenbach (DE); Dirk STÜBENER, München (DE)

(73) Assignee: ZF Friedrichshafen AG, Friedrichshafen (DE)

(21) Appl. No.: 19/397,197

(22) Filed: Nov. 21, 2025

(30) Foreign Application Priority Data
Nov. 22, 2024 (DE) 10 2024 211 238.0
Mar. 30, 2025 (DE) 10 2025 110 880.3

(51) Int. Cl. H02H 7/06; G01R 31/34; G01R 31/36

(52) U.S. Cl. CPC H02H 7/06; G01R 31/34; G01R 31/3644

(57) ABSTRACT

A test panel has test stations connected via a DC-voltage bus with a DC-voltage connection terminal for test objects having a voltage source, where the test station includes a resonance converter with a transformer and a PWM generator configured to supply the primary side of the transformer with a PWM signal from the DC-voltage in the DC-voltage bus when supplied with an operating voltage. The test station has a switch arranged between the secondary side of the transformer and the DC-voltage connection terminal for interrupting the electrical connection. A safety control unit, when in a safety condition, can disconnect the PWM generator from the operating voltage and open the switch. In a room arrangement, the test panel is distributed over at least two rooms so that the DC-voltage connection terminal is located in a first room and at least part is located in a second room.

### RELATED APPLICATIONS

This application claims the benefit of and right of priority under 35 U.S.C. § 119 to German Patent Application no. 10 2024 211 238.0, filed on 22 Nov. 2024, and to German Patent Application no. 10 2025 110 880.3, filed on 20 Mar. 2025, the contents of which are incorporated herein by reference in their entireties.

### FIELD OF THE DISCLOSURE

The invention relates to a test panel. A relevant test panel in the present context serves for the electrical testing of test objects, for example electric drive units or drive batteries of electric vehicles, using DC-voltage with comparatively high powers in the tens of kilowatts range. One of the test objects can be or is connected in each case at several test stations of the test panel. Then, the test objects can draw electrical power from the test station concerned or deliver power thereto.

### BACKGROUND

From WO 20212/174278 A1 it is known that electrically operated test stations as a rule comprise inverter arrangements with a plurality of inverters, whether for testing drivetrains of electric vehicles, hybrid vehicles, conventional vehicles with internal combustion engines, the mechanical components such as the transmission, or the battery storage systems themselves. In fact, battery storage systems are often tested in parallel, in such manner that a number of battery cells, battery modules, or battery packs are tested at the same time with inverters arranged in parallel.

### SUMMARY

The purpose of the present invention is to propose improvements relating to a test panel.

This objective is achieved by a test panel as disclosed herein. Preferred or advantageous embodiments of the invention and other invention categories emerge from the present disclosure, including the description given below and the attached figures.

The test panel is designed for test objects, i.e., for the testing of, or for the connection of, test objects. The test panel serves for the electrical testing of the test objects. The test objects are tested with the help of an electric current to be fed into and/or drawn from the test object concerned. For this, the test panel is of such a size that the test object can be exposed to a comparatively high electric power. Accordingly, the test panel is designed to impose comparatively high electric loads on the test objects. The nominal value or maximum value of the electric power for each test object is typically 250 kW to 1 MW, with a typical voltage of around 200 V to around 800 V and a nominal current typically of 1000 A to 2000 A.

The test panel contains a DC-voltage bus for conducting a DC-voltage.

The test panel contains at least one energy source. The energy source can feed electric power into the rest of the test panel or, if necessary, also can draw power from it. Thus, the terms “source/production/etc.” should here be understood broadly. For example, the “energy source” is in this case designed bidirectionally if necessary, and if so required, can also be operated as an energy sink.

Each energy source comprises a first DC-voltage interface in order to deliver DC-voltage power to the DC-voltage bus and in particular also draw it therefrom.

The test panel also comprises a plurality of test stations. Each test station serves for the testing or connection of one test object.

Each test station has a second DC-voltage interface for the DC-voltage bus. Each of the test stations also has a DC-voltage connection terminal. This serves for the connection of a test object in each case.

In the test panel all the test stations are connected with their second DC-voltage interfaces to the DC-voltage bus. Moreover, all the energy sources are connected with their first DC-voltage interfaces to the DC-voltage bus. Thus, all the energy sources and all the test stations are connected electrically conductively to one another by the DC-voltage bus, and these components can exchange energy with one another by way of the DC-voltage bus.

Each of the test stations comprises a resonance converter. Each resonance converter contains a transformer, which in turn has a primary side and a secondary side. The primary side faces the second DC-voltage interface and is electrically connected thereto, while correspondingly the secondary side is connected to the DC-voltage connection terminal.

Each of the test stations contains a PWM generator. This is designed to supply the transformer on its primary side with a PWM signal produced from the DC-voltage at the second DC-voltage interface. However, the PWM generator only does that when it is supplied with an operating voltage. In the absence of an operating voltage the PWM generator cannot produce a PWM signal. The transformer is then exposed to no signal or at any rate to a DC voltage. But then, no energy is transmitted from the primary to the secondary side. Thus, on the secondary side no voltage, but in particular no power can be produced. Accordingly, no voltage is also produced at the DC-voltage connection terminal. The latter is thus switched to a voltage-free condition.

Each of the test stations also contains a switch, which is arranged and connected between the secondary side of the transformer and the DC-voltage connection terminal of the test station. In particular, the switch is arranged in the DC-voltage path of the test station. The switch is at least a single-pole switch, in particular a two-pole switch. The switch serves to interrupt or establish an electrical connection between the secondary side and the DC-voltage connection terminal, depending on whether it is open or closed. When the switch is open an additional protection (additional to the above-mentioned operating voltage) is established, in order to switch the DC-voltage connection terminal to a voltage-free condition.

The test panel contains a safety control unit; in particular each test station contains a safety control unit. This is designed optionally to be in a safety condition or to be switched to it. The safety condition can be activated or deactivated individually at each test station. In the safety condition the safety control unit is designed, in relation to the selected test station or stations (with the safety condition activated for them) to adopt the following measures: in the safety condition the safety control unit disconnects the PWM generator at the test station concerned from the operating voltage and keeps it disconnected. In addition, it opens the switch in the test station concerned and keeps it open.

In other words, at the test station concerned, the safety control unit ensures that in the safety condition the PWM generator is no longer supplied with the operating voltage so that it cannot any longer produce a PWM signal to transmit to the transformer. Thus, power transmission via the transformer is prevented. Furthermore, the safety control unit interrupts the electrical connection between the transformer or its secondary side and the DC-voltage connection terminal in the test station concerned. Consequently, the DC-voltage connection terminal at the test station concerned has no voltage and no power.

In contrast, if at one or more test stations the safety device is not in the safety mode but is being operated, for example, in a normal mode, then the operating voltage is supplied to the PWM generator so that the latter can produce the PWM signal and close the switch, thereby producing an electrical connection between the transformer and the DC-voltage connection terminal. The test station can then be used for testing test objects.

Thanks to the measures it is ensured that in the safety condition, in the transformer which is then out of action (in a galvanically separating condition) the primary and secondary sides of the transformer are galvanically separated. The DC-voltage connection terminal is thus only still connected “as far as the secondary side” to the transformer and is in other respects separated galvanically from the rest of the test panel (primary side, intermediate circuit, DC-voltage bus, energy source). As a second safety stage or to provide redundancy, in addition the electric connection between the secondary side and the DC-voltage connection terminal is interrupted by the switch.

Thus, work can be carried out safely at the DC-voltage connection terminal since it is switched to a voltage-free condition, even though the test panel as such can remain in operation and therefore, if necessary, other DC-voltage connection terminals which are not in the safety condition can still be used for testing test objects.

In many cases a testing device such as a so-termed DC-box is initially connected at the output of the test station. Only to this can the actual test object (DUT: Device Under Test) be connected or connectable. In contrast, the DC-box (for example in the form of a switch cabinet) is connected permanently to the output of the test station. Handing operations on voltage-carrying parts, as they are to be made safe here, then strictly speaking take place at the output of the DC-box. Accordingly, the term “DC-voltage connection terminal” should in this context be understood broadly and can also be located downstream from the test station and remotely from it. However, the statements made here apply analogously. Viewed differently, the testing device could then also be understood to be part of the test station. The test station then ends at the outlet of the testing device with the DC-voltage connection terminal of the “test object” to be connected and is then reduced to the DUT.

In a preferred embodiment, the switch is not an isolator switch or a load-isolating switch. In this case the terms are to be understood in a narrow technical sense; see for example the Internet pages https://de.wikipedia.org/wiki/isolator-switch and https://de.wikipedia.org/wiki/load-isolating-switch, in each case accessed on 16 Jan. 2025. Thus, thanks to the safety concept it is possible to do without an expensive, elaborate and bulky isolating switch.

In a preferred variant of this embodiment, the switch is a contactor. This term too should be understood in the narrow technical sense; see for example the Internet page https://de.wikipedia.org/wiki/Sch%C3%BCtz_(switch), accessed on 16 Jan. 2025. By virtue of the safety concept according to the invention it is also possible to use comparatively advantageous, inexpensive and compact contactors for the reliable activation of the DC-voltage connection terminal, since besides putting the transformer out of operation the contactor is only incorporated as a redundant element in the safety concept.

In a preferred embodiment, the safety control unit comprises a safety device which is designed to secure the test station against re-connection of the operating voltage to the PWM generator and to switch of the test station concerned. This ensures that an inadvertent activation of the PWM generator or closing of the switch, and hence a hazard to people working at the DC-voltage connection terminal of the test station concerned, is excluded. Thus—after the DC-voltage connection terminal has been activated—it can be ensured in accordance with customary practice that a re-connection of the DC-voltage connection terminal is reliably prevented. Work can therefore be carried out at the DC-voltage connection terminal without danger. The safety device is for example a fastening means for a padlock that prevents a re-connection of the isolator switch if present or brought in.

In a preferred embodiment, the test panel comprises at least one operating element. This is designed, in the safety control unit, to activate the safety condition in at least one of the test stations. In other words, the operating element commands the safety control unit to switch off the operating voltage and the switch. The operating element is arranged at the DC-voltage connection terminal. An arrangement “at the DC-voltage connection terminal” is understood to mean that the operating element is located within a particular radius away from the correlated DC-voltage connection terminal, for example within a distance of at most 30 cm, at most 50 cm, at most 100 cm, at most 2 m or at most 5 m. Thus, there is a positional correlation between the DC-voltage connection terminal and the operating element. Accordingly, an operator can recognize intuitively that the operating element is associated with the corresponding DC-voltage connection terminal, in order to activate it. In particular the following is conceivable: with reference to many or all the DC-voltage connection terminals, the operating element is in all cases positioned closer to the DC-voltage connection terminal with which it is associated than to any other DC-voltage connection terminals.

In a preferred variant of this embodiment, the operating element is a remote control for the safety control unit a distance away from it. In other words, it is possible or is then the case that the operating element is located a distance away from the safety control unit in order to connect or secure the DC-voltage connection terminal in a voltage-free manner from there. Thus it is possible to position the safety control unit a distance away from the operating element, for example close to the PWM control unit, the transformer or the switch, etc., even if the DC-voltage connection terminal is located a comparatively large distance away from the PWM control unit/the transformer/the switch, for example in different rooms of a building or room arrangement of the rooms.

In a preferred embodiment, the DC-voltage connection terminal is connected to the rest of the test station by a supply lead and arranged a distance away from the rest of the test station. For example, the rest of the test station can be in a first room of a building/room arrangement, whereas the DC-voltage connection terminal is located in another room. For example, the rest of the test station, together with the generator, are in a specially cooled supply area whereas the DC-voltage connection terminal is in a test area for test objects.

In a preferred embodiment the test object is not or cannot be connected to the DC-voltage connection terminal by a plug-in connector. Particularly for the high-power tests of test objects considered in the present context, there must be a correspondingly reliable electrical high-power connection between the DC-voltage connection terminal and the test object. By not having a plug-in connector this can be done reliably. For example, the connection is made by direct contact or assembly by means of bus bars. However, thanks to the safety concept for activating the DC-voltage connection terminal, during the setting-up stage safer handling is possible even without plug-in connectors, for example connection to the bus bars.

In a preferred embodiment, the test station contains a monitoring unit. The monitoring unit contains an output unit. The output unit is arranged on the DC-voltage connection terminal. In respect of an arrangement “on the DC-voltage connection terminal”, the statements made above concerning the operating element apply correspondingly. The monitoring unit is designed, in the safety condition, to monitor whether at the test station concerned the PWM generator is in fact not being supplied with the operating voltage and whether the electrical connection by way of the switch between the secondary side of the transformer and the DC-voltage connection terminal has in fact been broken. In the event that at least one of those conditions is not fulfilled, the monitoring unit is designed to send out or issue a warning message to the output unit. In such a case, for safety reasons the monitoring unit also prevents the test station from being switched on again. Thus, reliable switching-off is ensured even if an individual fault occurs.

In a preferred variant of this embodiment, the test panel, in particular the monitoring unit, contains a self-diagnosis unit. This is associated with the monitoring unit and is designed to carry out a self-diagnosis of the functionality of the monitoring unit. The diagnosis is in particular based on monitoring an intermediate circuit voltage that occurs during operation at the output of the transformer and is stored in the step-down converter. Tested in particular is the discharging of that voltage within a certain maximum time.

If according to the diagnosis functionality is not confirmed, then the diagnosis unit is designed to change the test panel to a permanent error condition. “Permanent” means that the fault status cannot be re-set from within the test panel. Such an error condition can only be re-set again from outside the test panel, for example by a servicing technician. This provides a further safety stage, which also covers a defective function of the monitoring unit.

The stated objective of the invention is also achieved by a room arrangement as disclosed herein.

The room arrangement comprises at least two rooms and the test panel according to the invention. The test panel is distributed between at least two of the rooms in the room arrangement, in such manner that the DC-voltage connection terminal is arranged in a first of the rooms and at least part of the rest of the test panel is arranged in a second, other one of the rooms.

In particular, as already explained above, the operating element is located in the first room, namely as a remote control for the safety control unit located at least partially in the other room.

In particular, as already explained above, the DC-voltage connection terminal in the first room is connected by a supply lead to the rest of the test station, which is located at least partially in the other room.

The room arrangement enables a modular and advantageous structure of the test panel as a whole, so that parts of the test panel can be located in spaces specially designed for them. Thus, individual areas can be cooled or ventilated or heated, for example. Furthermore, individual areas can be accessed only by particular people/personnel circles (maintenance technicians/operating personnel/test personnel).

The invention is based on the following insights, observations or considerations, and can also be implemented in the following preferred forms. These embodiments are sometimes mentioned as “the invention” for simplicity. The embodiments can also contain parts or combinations of the embodiments described earlier or can correspond thereto, and/or can include embodiments not previously mentioned, if necessary.

According to the invention, safe activation of DC voltage sources (DC-voltage connection terminals) is achieved.

There is a combination of the reliable separation by means of the transformer and the redundant disconnection by means of the switch (in particular DC contactor) for achieving safe activation, in particular one that can be controlled remotely.

From practice, sometimes complicated activation via an AC main switch of the complete setup, i.e., the test panel (for example at the energy source), or an insecure disconnection of the DC output, is known. According to the invention, a high standard of reliable and safe activation is achieved, in particular activation that can be controlled remotely.

The invention relates to the following setups/topologies under consideration: the equipment under consideration consists of highly dynamic, feedback-capable DC voltage sources and sinks (test station) for the testing of electrical components (test objects) and for the simulation of batteries and other electrical storage means on test benches (testing modules). In this context typical test objects are drive units and storage components such as batteries, electric drive units, power converters, fuel cells, solar cells or supercapacitors.

With the topologies considered, from the busbars (DC-voltage connection terminal), respectively, a high DC power (typically 250 kW to 1 MW) is delivered at high voltages (up to 1500 V) and with large currents (up to 2000 A).

In this case one or more test stations can be connected to one energy source.

The invention is based on the following insights:

When setting up (changing the test object, specifically the DUT in a testing device), work has to be carried out on the busbars of the test station (DC-voltage connection terminal, or, if necessary, output of the testing device; see above), in order to be able to connect the test object directly to the bus-bars. The use of plug-in connectors with the large currents and high voltages involved is very troublesome and only conditionally possible or sometimes even not at all possible.

In this setting-up process, active components (components that can carry dangerous voltages) have to be touched. Accordingly, measures must be adopted in order to ensure protection against electric shock while setting up.

The basic rules for protection against electric shock are as follows:
voltage-carrying components must be protected against being touched. In this context that is not practicable since to be contacted, the rails have to be bare.
components that can be touched must not carry dangerous voltages. From this it follows that absence of voltage must be ensured.

In practice, the absence of voltage is ensured by complying with safety regulations. In this context there are two essential points: ensuring activation, and that re-connection does not occur. This requires secure separation, which can be achieved for example by switching equipment such as power switches, load-isolation switches, safety load-isolation switches, etc.

This gives rise to the following problems:

With the topologies in this case this would correspond to the disconnection and securing of the mains disconnect device (main switch) in the energy source. However, that has the following disadvantages:

The main switch may be in a distant room if the equipment is distributed over several rooms, which is also the case as a rule.

The relation between workplaces (location of the DC-voltage connection terminal or the test object or testing device) and the mains disconnection device (location of the mains disconnection device) must be established by plans or identification labels on which the installer should rely.

There is no intuitive relationship between the disconnection point (location of the mains disconnection device and the workplace (location of the DC-voltage connection terminal or the test object or testing device).

Switching off entails covering distances several times, which can result in inconvenient activity for an avoidance response.

Further test facilities (test stations) can be supplied by the same DC intermediate circuit (DC-voltage bus), which in some cases should remain in operation during the assembly work. In that case the main switch of the energy source cannot be switched off. Due to organizational pressure on the installer this can result in the installer working without prescribed activation.

The disadvantages can have the result that the safety prescriptions (organizational measures) are disregarded and work is carried out with the main switch turned on.

The background of the invention is the following risk assessment in relation to the safety risk:

In his activity the worker must work on the DC-box (DC-voltage connection terminal/testing device), in order to install the test object (DUT) there. During this he should do the same on the bus bar of the unit.

Owing to the very dangerous situation and the associated high risk, a high-risk scenario exists (risk level 4 out of 5 possible steps).

The bus bars are electrically active components with voltages up to 1000 V DC.

The risk is that of electric shock, which can result in serious injury or death.

Accordingly, a high level of technical and functional safety is demanded.

The risk assessment is based on the following assumptions:

Serious (irreversible) damage or death can be expected

Exposure is rare or not very frequent and/or of short duration.

The invention is based on the following concept:

Owing to the high danger potential, in combination with the foreseeable misapplication or avoidance response when activating by means of the main switch, it must be possible to activate the system safely directly at the connection point (DC-voltage connection terminal/testing device/DC-box).

For reasons of space and costs, no additional disconnection switches (in the narrow sense; see above) should be fitted at the connection point, but safe activation should take place remotely from the connection point to the rest of the test panel. Furthermore, it should be possible to use switch and adjustment devices already present in test panels in common practice.

In the test panel known from practice two mechanisms are available for this:
1. Output contactor on the DC side (on the DC-voltage connection terminal)
2. Isolating transformers for the primary/secondary separation (in the resonance converter).

### Re-1

According to the standards, fuses are not acceptable as stand-alone protection against electric shock. However, since independently of that specification they can make a contribution toward the diversity and redundancy of the isolation, the DC-side output connectors are included in the protection concept.

### Re-2

Transformers with reliable separation are generally accepted in practice as protection against electric shock, if they produce safe voltage levels on the secondary side. These include among others all types of consumer mains units/chargers for electronic equipment. In contrast to such equipment, the isolating transformers in the test station produce an output voltage which, if contacted, is life-threatening. Creating safe separation with such transformers means that such transformers must be switched off, i.e. any energy flow by way of these transformers must be prevented.

An energy flow by way of a transformer is only possible when an alternating voltage is applied at its input connection terminals. This alternating voltage is produced in the test panel by an inverter (part of the resonance converter) which is actuated by a PWM signal from an internal control unit (PWM generator).

The principle of safe separation at the transformer is based on the fact that the control unit (PWM generator) that produces and transmits the PWM signal is separated from the operating voltage via a safe path. Without the PWM, the inverter cannot produce any alternating voltage even if there are faulty components, so energy transmission via the transformers is no longer possible.

With the combination of output contactors and separation by means of transformers, in the test panel a method which is just as good or even better for “activating” and “guarding against re-connection”, compared with the methods established in practice, is achieved.

This is ensured in particular by continuous monitoring (monitoring unit) of the two redundant disconnection paths and the internal diagnosis of the functionality of the function (diagnosis unit). The diagnosis function includes in particular the monitoring of the discharge of any dangerous intermediate circuit voltage in the equipment within a certain time. If that condition is not satisfied, the equipment changes to a permanent error condition which, in particular, can only be re-set by a service technician, since a hardware fault must be expected.

### BRIEF DESCRIPTION OF THE DRAWING

Further features, effects and advantages of the invention emerge from the following description of a preferred example embodiment of the invention, and form the sole attached figure, which shows, in the form of a schematic illustration of the principle:

FIG. 1: A test panel with two test stations and an energy source, represented as a schematic block circuit diagram.

### DETAILED DESCRIPTION

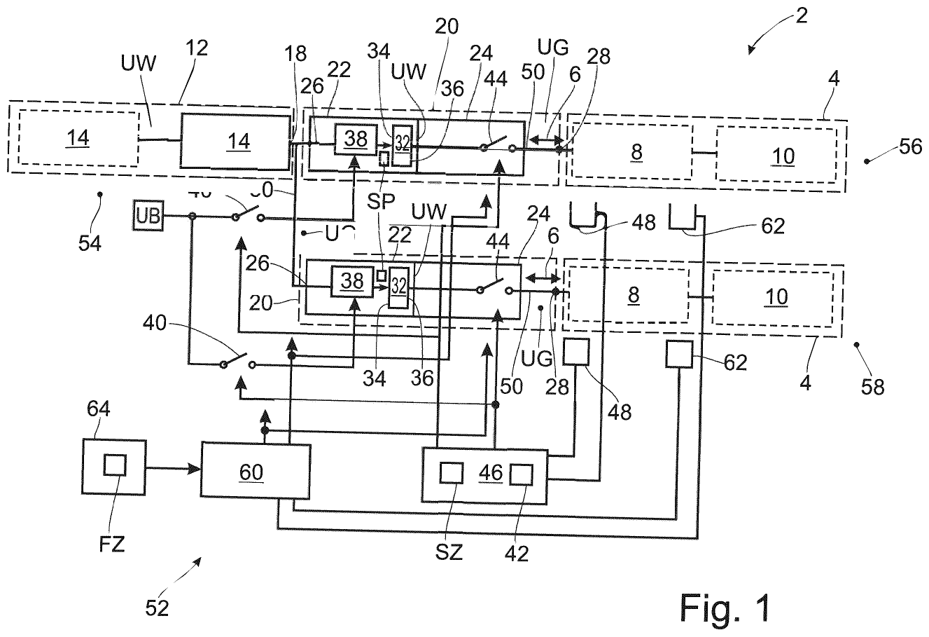

FIG. 1 shows a test panel 2, in this case for 2-pole test objects 4. In the example shown there are in fact two test objects 4 connected to the test panel 2. With the help of the test panel 2, an electrical test is carried out on the test objects 4. For that purpose, an electric high power 6, in this case of up to 1 MW—depending on the test—is fed into the test objects 4 or drawn from them. The high power 6 is indicated in the example by a double-arrow.

In the example each test object 4 is represented in the form of a testing device 8, in this case a so-termed DC-box, and the actual test object in the form of a DUT 10 (Device Under Test). Here, the two DUTs 10 are a drive battery and a drive motor of an electric vehicle. The DC-box serves for connecting the actual test object in the form of the DUT 10 to the test panel 2.

The test panel 2 contains an energy source 12, which in turn comprises a generator 14 and a converter 16. In operation the generator 14 provides an alternating voltage UW, in this example a three-phase alternating voltage of 400 V. The converter 16 is connected to the generator 14 and serves to convert the alternating voltage UW in this case into a two-pole (plus and minus poles) DC voltage UG, which in this case is applied at a two-pole DC-voltage interface 18 of the inverter 16 or the energy source 12.

The test panel 2 also has two test stations 20. In this case each of the test stations 20 serves for the likewise two-pole connection of just one of the test objects 4.

Each test station 20 contains a resonance converter 22 and a step-down converter 24. The resonance converter 22 or the test station 20 comprises a second two-pole DC-voltage interface 26. The step-down converter 24 or test station 20 has on the side facing away from the resonance converter 22 a two-pole DC-voltage connection terminal 28 for the respective test object 4. The resonance converter 22 converts the DC voltage UG at the second DC-voltage interface 26 into an alternating voltage UW, which in turn is converted by the step-down converter 24 into a direct current UG at the DC-voltage connection terminal 28.

Where appropriate, the term DC-voltage connection terminal should also be understood to mean the output of the testing device 8 to which the DUT 10 is connected, as already explained earlier, when that output is to be secured as an “interface”, in order to be able to carry out work there, for example the installation of DUTs 10, in a safe manner.

The test panel 2 also comprises a two-pole DC-voltage bus 30. The first DC-voltage interface 18 and the second DC-voltage interfaces 26 are connected to the DC-voltage bus 30 (whose two bus-bars are not shown), in order to connect these components electrically to one another. Thus, the DC-voltage bus 30 distributes the DC voltage UG between the energy source 12 and the test stations 20.

Thus, the DC-voltage bus 30 forms a DC-voltage intermediate circuit in the test panel 2 and in this case carries a direct current UG of 825 V during operation.

Each resonance converter 22 contains a transformer 32, which has a primary side 34 and a secondary side 36. The primary side 34 faces toward the second DC-voltage interface 26 and the secondary side 36 faces toward the DC-voltage connection terminal 28.

Each test station 20 also comprises a PWM generator 38. In each case this can be supplied with an operating voltage UB when an operating switch 40, here to be understood as symbolic, is closed. The respective PWM generator 38 is designed-always and only when it is supplied with the operating voltage UB, to supply the primary side 34 of the transformer 32 with a PWM signal PS, which signal is or will be produced from the DC voltage UG at the second DC-voltage interface 26.

Each of the test stations 20 also contains a switch 44 arranged between the secondary side 36 of the transformer 32 and the DC-voltage connection terminal 28. The position of the switch 44 in FIG. 1 should again be understood symbolically, and it does not necessarily have to be in the step-down converter 24. Here, the switch 44 is not an isolator switch, but rather a contactor.

The switches 44 serve to interrupt or to form the electrical connection between the DC-voltage connection terminal 28 and the transformer 32 or its secondary side 36.

The test panel 2 also contains a safety control unit 46 which is associated in equal measure with the two test stations 20. The safety control unit 46 is designed, in relation to one or more of the test stations 20, to be changed to a safety condition SZ. In that condition, in the test station 20 concerned it disconnects the PWM generator 38 from the operating voltage UB, in this case by opening the switch 40, and keeps it disconnected. In addition, in the safety condition SZ it opens the switch 44 in the test station 20 concerned and keeps it open.

This happens selectively for the test stations 20 chosen, whereas in principle the rest of the test stations 20 in the test panel 2 can remain operational.

The safety control unit 46 also contains a safety device 42. This guards against re-connection of the operating voltage UB (closure of the switch 40) and closure of the switch 44 with reference to the test stations 20 concerned. Thus, it is ensured that at the test stations 20 concerned no voltage is inadvertently applied again to the DC-voltage connection terminal 28 so that, for example, people would be endangered there.

The test panel 2 also contains operating elements 48, namely one for each test station 20. The operating elements 48 are designed to change the safety control unit 46 associated with the test station 20 concerned to the safety condition SZ and activate the latter for the test station 20 concerned. For this, the operating element 48 is in each case arranged on the relevant DC-voltage connection terminal 28, i.e. here, in the local surroundings or within range of an operator who is present at the DC-voltage connection terminal 28 and wants to work on it. Thus, the operator can actuate the operating element 48 close to or where he is and thereby switch off any voltage from the DC-voltage connection terminal 28 and work on it safely.

In the present case the operating elements 48 are in the form of remote controls, since the safety control unit 46 is located a distance away from the operating elements 48.

FIG. 1 also shows a room arrangement 52 with a first room 54, a second room 56 and a third room 58. The energy source together with the safety control unit 46 is arranged in the first room 54, the upper test station 20 in the figure together with its operating element 48 is arranged in the second room 56 and the lower test station 20 in the figure, together with its operating element 48, is arranged in the third room 58.

The respective DC-voltage connection terminals 28 are also arranged in the second room 56/third room 58 and in each case connected by way of a supply line 50 to the rest of the test station 20 in the first room 54, here the step-down converter 24. The DC-voltage connection terminal 28 is therefore arranged a distance away from the rest of the test station 20 and is only connected to it by the supply line 50.

Thus, FIG. 1 also shows the room arrangement 52. This comprises the first room 54, in which both the energy source 12 and also the (rest of the) test station 20 are located. The first room 54 is air-conditioned. The room arrangement 52 also comprises the second room 56 and a third room 58. Thus, the first room 54 constitutes a supply space for the test panel 2. The second and third rooms 56 and 58 are testing rooms. The test objects 4 are present in those rooms. In this case the testing devices 8 are permanently fixed switch cabinets in the second room 56 and the third room 58, which are connected to actual test rigs which are not illustrated in more detail in the figure. In the test rigs the actual DUTs are connected to the testing devices 8 in order to be tested in each case.

The operating elements 48 are located in the second room 56 and the third room 58, and are therefore unambiguously associated with the DC-voltage connection terminal 28 in the second room 56 or the third room 58 in order to switch them, properly identified, quickly to the voltage-free condition. The supply lines 50 run from the first room 54, respectively both to the second room 56 and to the third room 58.

In this case, the test objects 4 are not connected to the DC-voltage connection terminals 28 by plug-in connections but by busbars (not shown), so that for their connection work has to be carried out directly on the uninsulated busbars. Specifically, the busbars have to be manipulated at the points between the testing device 8 and the DUT 10.

The test panel 2 also comprises a monitoring unit 60 with output units 62. The output units 62 are also arranged on the DC-voltage connection terminals 28 concerned in the second room 56 and the third room 58. The monitoring unit 60 is designed to monitor, in the safety condition SZ, whether for the test station 20 concerned the PWM generator is in fact not supplied with the operating voltage UB and whether the electrical connection between the transformer 32 and the DC-voltage connection terminal 28 is in fact interrupted by the switch 44. If not, the monitoring unit 60 is designed to issue a warning message via the output unit 62 concerned.

Furthermore, a self-diagnosis unit 64 is associated with the monitoring unit 60. This is designed to carry out a self-diagnosis of the functionality of the monitoring unit 60. If its functionality is not assured, the monitoring unit is designed to change the test panel 2 to a permanent error condition FZ. This can only be reset from outside the test panel 2, in this case by a servicing technician, as soon as the functionality is restored.

### Indexes

2 Test panel
4 Test object
6 High-power
8 Testing device
10 DUT
12 Energy source
14 Generator
16 Inverter
18 First DC-voltage interface
20 Test station
22 Resonance converter
24 Step-down converter
26 Second DC-voltage interface
28 DC-voltage connection terminal
30 DC-voltage bus
32 Transformer
34 Primary side
36 Secondary side
38 PWM generator
40 Operating switch
42 Safety device (re-connection)
44 Switch
46 Safety control unit
48 Operating element
50 Supply line
52 Room arrangement
54 First room
56 Second room
58 Third room
60 Monitoring unit
62 Output unit
64 Self-diagnosis unit
UW Alternating voltage
UG Direct voltage
UB Operating voltage
PS PWM signal
SZ Safety condition
FZ Error condition

1. A test panel (2) for the electrical testing of test objects (4) with the help of a high electric power to be fed into it and/or drawn from it under direct voltage (UG), the test panel comprising:
a DC-voltage bus (30) for conducting a direct voltage (UG);
at least one energy source (12) having a first DC-voltage interface (18) for the DC-voltage bus (30);
a plurality of test stations (20) for one of the test objects (4), each of the plurality of test stations having a second DC-voltage interface (26) for the DC-voltage bus (30) and a DC-voltage connection terminal (28) for the test object (4) concerned;
wherein all the test stations (20), with all the energy sources (12), are connected to one another via respective second DC-voltage interfaces (26) by the DC-voltage bus (30), by way of their first DC-voltage interfaces (18);
wherein each of the test stations (20) contains a resonance converter (22), which contains a transformer (32) with a primary side (34) facing toward the second DC-voltage interfaces (26) and a secondary side (36) facing toward the DC-voltage connection terminal (28);
wherein each of the test stations (20) contains a PWM generator (38), which is configured, when supplied with an operating voltage (UB), to supply the primary side (34) with a PWM signal (PS) produced from the DC voltage (UG) at the second DC-voltage interface (26);
wherein each of the test stations (20) contains a switch (44) arranged between the secondary side (36) and the DC-voltage connection terminal (28), in order to interrupt an electrical connection between the secondary side (36) and the DC-voltage connection terminal (28); and
a safety control unit (46), configured in a safety condition (SZ) to disconnect the PWM generator (38) from the operating voltage (UB) and keep it disconnected and to open the switch and keep it open.

2. The test panel (2) according to claim 1, wherein the switch is not an isolator switch or a load-isolator switch.

3. The test panel (2) according to claim 2, wherein the switch is a contactor switch.

4. The test panel (2) according to claim 1, wherein the safety control unit (46) comprises a safety device (42) configured to prevent re-connection of the operating voltage (UB) to the PWM generator and switching-on of the switch again.

5. The test panel (2) according to claim 1, wherein the test panel (2) comprises at least one operating element (48) configured to activate the safety condition (SZ) in the safety control unit (46) for at least one of the test stations (20), the operating element (48) being arranged on the DC-voltage connection terminal (28).

6. The test panel (2) according to claim 5, wherein the operating element (48) is a remote control for the remotely arranged safety control unit (46).

7. The test panel (2) according to claim 1, wherein the DC-voltage connection terminal (28) is connected to the rest of the test station (20) by a supply line (50) and is arranged a distance away from the rest of the test station (20).

8. The test panel (2) according to claim 1, wherein the test object (4) is not or cannot be connected to the DC-voltage connection terminal (28) by means of a plug-in connection.

9. The test panel (2) according to claim 1, wherein:
each test station (20) of the test panel (2) contains a monitoring unit (60) with an output unit (62), which is arranged on the DC-voltage connection terminal (28), and
wherein the monitoring unit (60) is configured, in the safety condition (SZ), to monitor whether the PWM generator (38) is in fact not being supplied with the operating voltage (UB) and whether the electrical connection by way of the switch (44) is in fact interrupted, and if not, to issue a warning message via the output unit (62).

10. The test panel (2) according to claim 9, wherein each test station (20) of the test panel (2) contains a diagnosis unit (64) which is associated with the monitoring unit (60) and configured to
(i) carry out a self-diagnosis of the functionality of the monitoring unit (60),
(ii) determine that the functionality is not confirmed, and
(iii) to change the test panel (2) to a permanent error condition (FZ).

11. A room arrangement (52) comprising:
at least two rooms (54, 56, 58); and
the test panel (2) according to claim 1, wherein the test panel (2) is arranged distributed over at least two of the rooms (54, 56, 58) (52) in such manner that the DC-voltage connection terminal (28) is located in a first one of the rooms (54, 56, 58) and at least part of the rest of the test panel (2) is located in a second one of the rooms (54, 56, 58).
